(19) United States
(12) Patent Application Publication
(10) Pub. No.: US 2009/0027859 A1
(43) Pub. Date: Jan. 29, 2009

(54) Surface mounted heat sink and electromagnetic shield

(76) Inventor: Lawrence M. Giacoma, Plano, TX (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 11/881,398

(22) Filed: Jul. 26, 2007

(51) Int. Cl. H05K 7/20; B21D 53/02; H05K 9/00; H05K 3/34

(52) U.S. Cl. 361/709; 29/840; 29/890.03; 361/818

(57) ABSTRACT

A single-piece, high performance, inexpensively fabricated heat sink and electromagnetic interference (EMI) shield makes thermal contact with a heat generating device. Capillary forces exerted on the heat sink by cooling flowed solder draw the heat sink toward the PCB. The heat sink attaches directly to a printed circuit board (PCB), thus not stressing ball grid array (BGA) solder joints between the heat generating device and the PCB in applications with BGAs. The heat sink does not require any special tools for installation or removal nor any additional PCB space. The heat sink is designed to allow automated surface mounting techniques, such as pick and place. The single-piece construction eliminates the need for a separate clip, thereby increasing heat transfer area.

### BACKGROUND OF THE INVENTION

As integrated circuit technology has improved, substantially greater functionality has been incorporated into devices. Along with this expanded functionality, the size of devices has diminished resulting in higher clocking frequencies and increased power consumption. As a consequence, the integrated circuit devices of today generate more heat while possessing smaller surface areas to dissipate the heat. Therefore, it is important to have a high rate of heat transfer from the integrated circuit package to maintain the temperature of the integrated circuit within safe operating limits. Excessive heat may adversely affect the performance of the circuit, cause permanent degradation of its components and increase failure rates.

A heat sink may be used for transferring heat away from a heat source, such as an electronic component or printed circuit board (PCB), to maintain the component within an optimum or safe operating temperature range, so that the component can operate continuously within safe thermal operating limits.

Conventional heat sinks typically contain a plurality of fins or rods that extend from a base that contacts the heat generating integrated circuit. Some heat sinks employ securing mechanisms that enlarge or exceed the heat sink envelope. This increases the footprint of the electronic component/heat sink assembly, thereby reducing the surface area of the PCB available for other circuit elements and potentially imposing a limit on the height of nearby elements on the PCB.

In addition to producing heat, integrated circuits radiate radio frequency (RF) emissions which may cause electromagnetic interference (EMI). EMI can cause other devices to malfunction. Typically, an EMI shield is used to reduce EMI. EMI shields typically take a form of a chassis element which extends around the entire electronics compartment of the computer or other device producing RF emissions. EMI shields limit electromagnetic radiation from entering or exiting sections of the PCB containing electrical components.

### SUMMARY OF THE INVENTION

One example embodiment of a heat sink, and corresponding method for securing the heat sink to a component, includes a contact structure with a conduction side and a convection side. The conduction side is configured to be in thermal communication with a heat generating device. Extending outward from the convection side of the contact structure are a plurality of thermally conductive elements. An attachment structure is configured to be coupled to a support structure, by less than or equal to a thickness of the attachment structure, to which the heat generating device is coupled. The attachment structure extends outward from the conduction side of the contract structure. The attachment structure defines a cavity having a length and a width defined by the length and the width of the attachment structure and the conduction side of the contact structure. The cavity also has a depth defined by the height of the heat generating device when coupled to the support structure. The conduction side of the contact structure contacts the heat generating device in a configuration in which both the attachment structure and the heat generating device are coupled to the support structure.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating example embodiments of the present invention.

FIG. 1A is an isometric diagram of a heat sink.

FIG. 1B is an isometric diagram of the heat sink of FIG. 1A in application with a heat generating device configured to be secured via a ball grid array (BGA) to a printed circuit board (PCB).

FIG. 1C is an isometric diagram of the heat sink, heat generating device and PCB of FIG. 1B illustrating additional features of the heat sink.

FIG. 2 is a cross sectional diagram of the heat sink and the heat generating device illustrating solder wicking features of an attachment structure to draw flowed solder by capillary, or other, forces.

FIG. 3 is a force diagram of a combination of the attachment structure and the contact structure in an example embodiment of the present invention annotated with forces exerted by the attachment structure on the PCB and forces exerted by the contact structure on the heat generating device.

FIG. 4 is a diagram of the heat sink further including a gap pad material to account for any excess height of the cavity and ensure thermal communication between the heat generating device and the heat sink.

FIG. 5 is a top view diagram of a heat sink with an attachment structure having faces that extend from a contact structure at an angle.

FIG. 6 is a flow diagram illustrating a method by which a heat sink may be secured.

FIG. 7 is a flow diagram illustrating a method by which heat may be dissipated.

FIG. 8 is a flow diagram illustrating a method of manufacturing a heat sink.

FIG. 9 is a flow diagram illustrating a method for preparing a circuit board for receiving an electronic component.

FIG. 10 is a diagram of an example mask, according to an example embodiment of the present invention, with a solder paste pattern corresponding to a pattern of structural components on an attachment structure of a heat sink.

### DETAILED DESCRIPTION OF THE INVENTION

A description of example embodiments of the invention follows.

Conventional heat sinks and clips for their attachment are inefficient, expensive to produce and bulky. Conventional heat sinks typically include both a body and a fastener. The fastener may be a curved piece that applies pressure on an electronic component to which the heat sink is applied when installed. However, such fasteners reduce the available convection surface area of heat sinks, thereby reducing their efficiency. Other conventional heat sinks employ spring action for securing the body to the electronic component, but require special modification of the printed circuit board (PCB). Further, conventional heat sinks require screws, push pins, clips, anchors or other forms of mechanical attachment that are additional parts beyond the body, itself, which takes up valuable surface area on the PCB, and block air flow to the convection surfaces of the heat sink.

Further, conventional methods of securing a heat sink to an integrated circuit or other heat generating device can weaken ball grid array (BGA) solder connections between the integrated circuit and the PCB through application of stresses. In a BGA, balls of solder may be adhered to the bottom of the package, e.g., the integrated circuit package, which is placed on a PCB that carries copper pads in a pattern corresponding to the solder ball pattern. The assembly is then heated, either in a reflow oven or by an infrared heater, causing the solder balls to melt. Surface tension causes the molten solder to hold the package in alignment with the circuit board, at the correct separation distance, while the solder cools and solidifies. Conventional clip-on heat sinks apply a bending moment to the heat generating device, which stresses the solder balls-to-PCB connections and decreases component reliability or useful life. Without a heat sink, the outer balls generally fail over time due to heating and inherent stresses. By adding more stress through an application of a heat sink, failures occur even quicker and more often.

Moreover, some heat sinks take an additional role of shielding electrical components from electromagnetic interference (EMI). These heat sinks may rely on many different plates, with springs and screws securing them to a PCB. However, such heat sinks require many small, custom parts with a certain amount of tooling or machining, thereby making them expensive to produce. Other heat sinks provide EMI shielding by being soldered directly to the PCB. However, such heat sinks can take up significant PCB surface and also require certain amounts of tooling or machining.

A heat sink according to an example embodiment of the present invention includes a contact structure with a conduction side and a convection side. The conduction side is configured to be in thermal communication with a heat generating device, and the convection side is configured to be in thermal communication with the heat generating device via the conduction side. The heat sink includes a plurality of thermally conductive elements extending outward from the convection side of the contact structure and an attachment structure extending from the conduction side of the contact structure defining a cavity. The attachment structure is configured to be connected, by less than or equal to a thickness of the attachment structure, to a surface of a member to which the heat generating device is connected. The cavity has a volume defined by the length and width of the contact structure and at least the height of the heat generating device as coupled to the member.

The attachment structure may also define a solder wicking feature configured to wick solder in a state of flow and draw the attachment structure toward the member during a transition of the solder from the state of flow to a state of being a solid. The wicking feature may be within a thickness of the attachment structure. The attachment structure may also define a flange extending substantially parallel to the surface of the member.

The attachment structure may extend substantially perpendicularly from the conduction side to the member, or may extend non-perpendicularly at an angle from the conduction side to the member.

The thermally conductive elements may provide more convection surface area than plate elements with flat surfaces. The thermally conductive elements may be configured to increase airflow across them. The thermally conductive elements may define a pick and place feature. A pick and place feature may be included in place of at least one thermally conductive element.

The contact structure, in combination with the attachment structure, may substantially encompass the heat generating device on five sides to contain electromagnetic interference (EMI) radiation generated by the heat generating device and provide EMI immunity for the heat generating device.

The attachment structure may include structural components selected from a group consisting of pegs, slots, ridge or solder wicking.

As deployed on a circuit board member, the attachment structure may have a thickness sufficiently thin to be mechanically between the heat generating device and AC filter capacitors coupled to the heat generating device. The cavity may also be configured to encompass other devices in addition to the heat generating device, such as the AC filter capacitors.

In another example embodiment, a heat sink includes a contact structure with a conduction side and a convection side. The conduction side is configured to be in thermal communication with a heat generating device, and the convection side is configured to be in thermal communication with the heat generating device via the conduction side. The heat sink includes a plurality of thermally conductive elements extending outward from the convection side of the contact structure and an attachment structure extending from the conduction side of the contact structure defining a cavity. The attachment structure is configured to be coupled to a surface of a member to which the heat generating device is coupled. The cavity has a volume defined by the length and width of the contact structure and at least the height of the heat generating device as coupled to the member. The attachment structure also defines a solder wicking feature configured to wick solder in a state of flow and draw the attachment structure toward the member during a transition of the solder from the state of flow to a state of being a solid.

In some example embodiments, the heat sink may be secured by positioning the heat sink relative to a heat generating device in a configuration in which the heat sink contacts a solder paste pattern deposited on a surface of a member to which the heat generating device is coupled. The solder is then caused to enter a state of flow. The solder draws the heat sink toward the member during a transition of the solder from the state of flow to a state of being a solid, wherein simultaneous contact between the heat sink with the heat generating device and the surface of the member is maintained. The heat sink may be positioned via a pick and place feature.

According to an example embodiment of the present invention, a heat sink may be manufactured by forming a contact structure with a conduction side and a convection side, forming a plurality of thermally conductive elements extending outward from the convection side of the contact structure, and forming an attachment structure extending from the conduction side of the contact structure for a distance defining a cavity. The attachment structure is configured to be connected, by less than or equal to a thickness of the attachment structure, to a surface of a member to which the heat generating device is connected. The cavity has a volume defined by the length and width of the contact structure and at least the height of the heat generating device as coupled to the member.

According to another example embodiment of the present invention, a circuit board may be prepared for receiving an electronic component by applying a first surface mount solder paste pattern to a surface of the circuit board to receive an electronic component, and applying a second surface mount solder paste pattern to the surface of the circuit board, in proximity to the first surface mount solder paste pattern, to receive a heat sink configured to be surface mounted in an arrangement to draw heat from the electronic component. The second surface mount solder paste pattern has a thickness corresponding to the thickness of a solder wicking feature of the heat sink configured to wick solder in a state of flow and draw the heat sink toward the circuit board during a transition of the solder from the state of flow to a state of being a solid.

In one example embodiment, a mask may define a solder paste pattern corresponding to a pattern of structural components on an attachment structure of a heat sink. The pattern may have a thickness substantially corresponding to a thickness of a solder wicking feature of the heat sink. The solder paste pattern may further correspond to a pattern of structural components on a heat generating device.

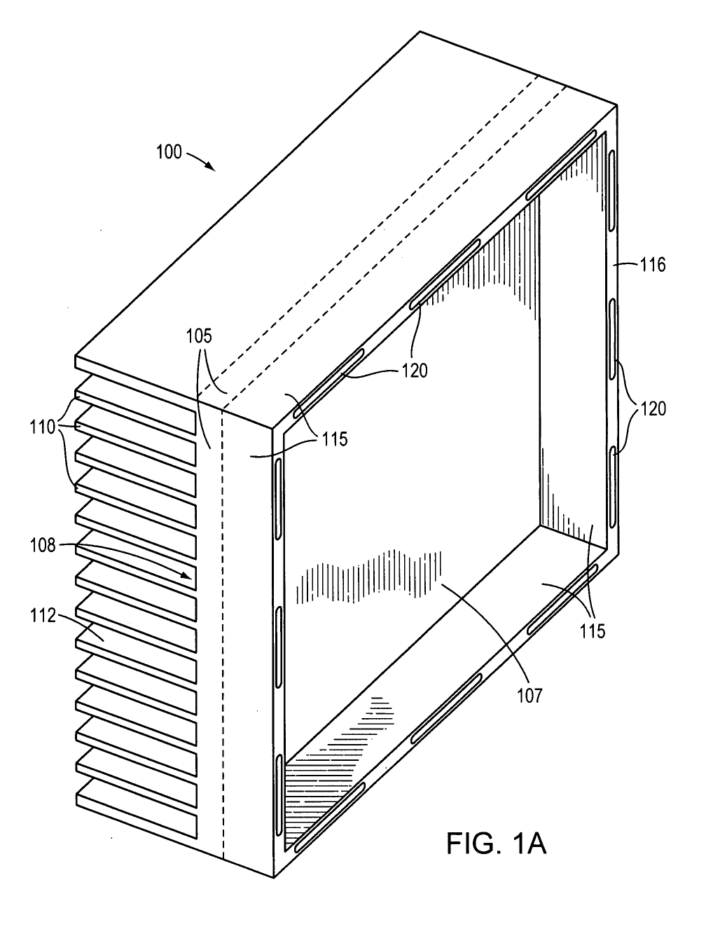

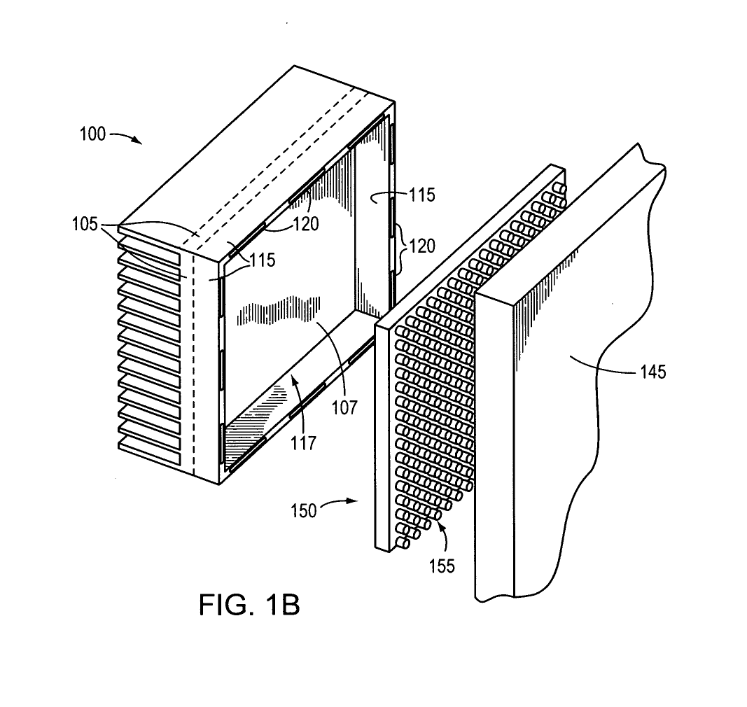

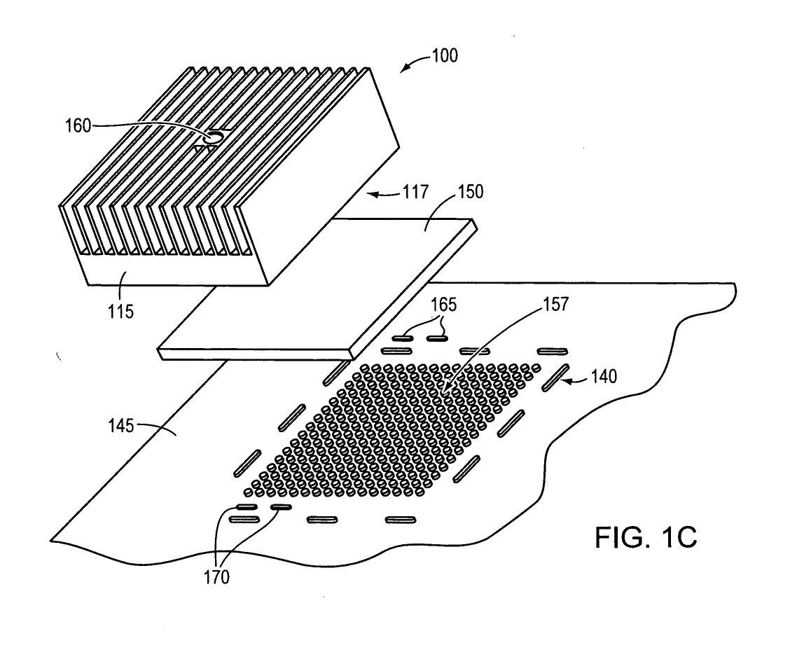

FIG. 1A is an isometric diagram of a heat sink. The heat sink 100 includes a contact structure 105, having a conduction side 107 and a convection side 108. The conduction side 107 is configured to be in thermal communication via direct or indirect contact with a heat generating device (not shown), such as an integrated circuit or a variety of other optical, electrical, or mechanical components. The heat sink 100 further includes a plurality of thermally conductive elements 110 extending outward from the convection side 108 of the contact structure 105. In this example embodiment, the thermally conductive elements 110 are flat surfaces 112; however, they may be wavy fins, having an undulating curvature across the convection side 108 or across their distance extending outward from the convection side, to provide more convection surface area (not shown) as understood in the art. Further, the thermally conductive elements 110 may be configured to increase airflow across them by defining narrowing airflow paths in a direction of airflow across them or being airfoil shaped, thereby increasing the efficiency of the heat sink 100. Here, the example thermally conductive elements 110 are aligned in a parallel manner such that air flows freely through the channels created by opposing thermally conductive elements 110.

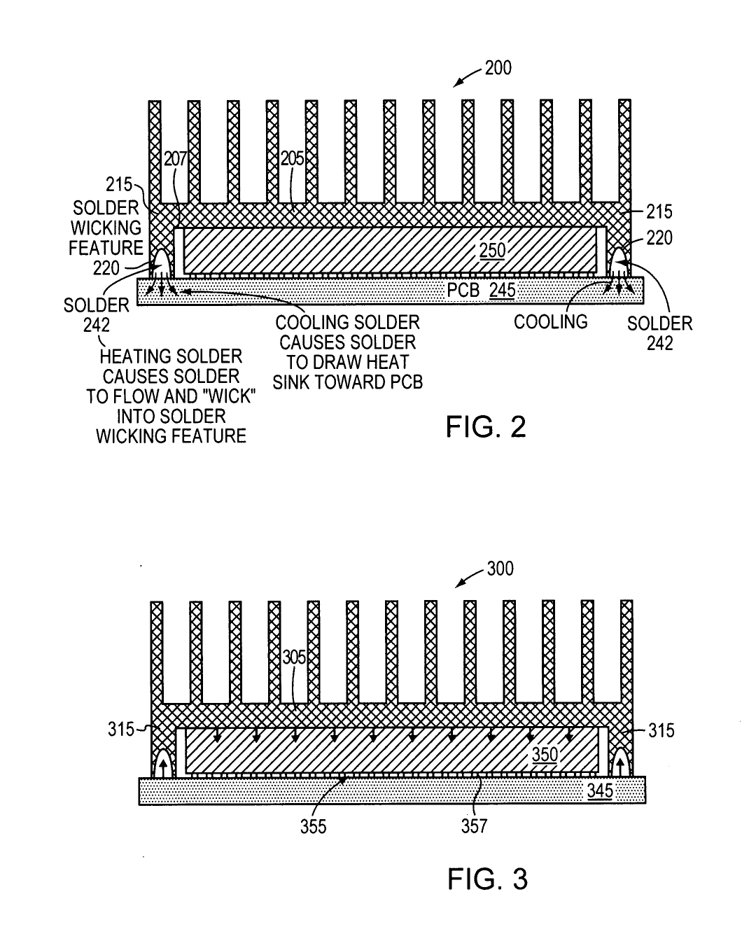

The heat sink 100 further includes an attachment structure 115 that extends substantially perpendicularly from the conduction side 107 of the contact structure 105. The attachment structure 115 further has a plurality of solder wicking features 120, in this example embodiment along a thickness of the attachment structure 115. The solder wicking features 120 may help secure the attachment structure 115 to a PCB and are described in greater detail with reference to FIG. 2. The attachment structure 115, in an additional example embodiment, may also extend non-perpendicularly at an angle from conduction side 107. In both of these example embodiments, the attachment structure 115 may further include a flange extending at an angle from the attachment structure 115 with the flange having wicking features 120 on a surface substantially parallel to the surface to which the attachment structure 115 will be attached (not shown).

FIG. 1B is an isometric diagram of the heat sink 100 of FIG. 1A illustrated in application with a heat generating device 150 secured via a BGA 155 to a PCB 145, the attachment structure 115 extends downward for a length defining a cavity 117. The cavity 117 has a length and width defined by the length and width of the attachment structure 115 and the conduction side 107 of the contact structure 105 and has a depth defined by the height of the heat generating device 150 when coupled to the PCB 145 via the BGA 155. The solder wicking features 120 may help secure the attachment structure 115 to the PCB 145 and are described in greater detail with reference to FIG. 2.

FIG. 1C is an isometric diagram of the heat sink 100, heat generating device 150, and PCB 145 of FIG. 1B illustrating additional features of the heat sink 100. The heat sink 100 is designed to allow automated surface mounting techniques In this example embodiment, a pick and place feature 160 provides a surface for a suction-based pick and place machine to appropriately position the heat sink 100 for soldering to the PCB 145.

During preparation of the PCB 145 for receiving the heat generating device 150, a first surface mount solder paste pattern 157 is applied to the PCB 145 for soldering the heat generating device 150 to the PCB 145. A second surface mount solder paste pattern 140 may be applied to the PCB 145 in proximity to the first surface mount solder paste pattern 157 for soldering the heat sink 100 to the PCB 145, typically in electrical connection with a ground plane that spans beneath the heat generating device 150 to provide EMI shielding below the device 150. The second solder paste pattern 140 corresponds to the locations of the solder wicking features (120 of FIGS. 1A and 1B) of the attachment structure 115. The heat sink 100 may be placed over solder paste pattern 140 by the pick and place machine. The solder paste patterns 140, 157 may be heated through a reflow process, thereby allowing the solder of the solder paste patterns 140, 157 to flow so that the heat generating device 150 and the heat sink 100 may be soldered to the PCB 145.

Because the heat sink 100 is substantially connected to the PCB 145, the heat sink 100 provides EMI shielding around the heat generating device 150. The heat sink 100 may also provide heat transfer and EMI shielding to other devices 170 within the cavity 117. Moreover, the heat attachment structure 115 may have a thickness (116 of FIG. 1A) sufficiently thin to be mechanically between the heat generating device 150 and AC filter capacitors 165 coupled to the heat generating device 150.

The heat sink 100 may be secured to and removed from the PCB 145 without use of special tools other than a heating mechanism and grip mechanism and uses substantially no additional PCB surface area beyond the heat-generating device 150. The heat sink 100 may be black anodized so that its surface is non-electrically conductive and may be fabricated through an extrusion process, machining process, or die casting process, for example, and is inexpensive to fabricate, in part, because it may be a single piece. The heat sink 100 may be tin plated to facilitate soldering the heat sink 100 to the PCB 145. Moreover, use of the heat sink 100 does not require special modification to the PCB 145 or any other member to which the heat generating device 150 is secured. Because the heat sink 100 is attached to the PCB 145, the heat sink 100 is able to draw additional heat from the PCB 145 directly, thereby providing increased cooling over traditional heat sinks.

FIG. 2 is a cross sectional diagram of the heat sink 200 and heat generating device 250 that illustrates a combination of solder 242 and the wicking features 220 of the attachment structure 215. When heated, the solder 242 flows and is caused to be drawn into the solder wicking features 220 by capillary forces or other forces, such as forced vacuum forces (active vacuum device not shown). As understood in the art, when solder cools, it shrinks. When the solder 240 cools, the shrinking that occurs causes the heat sink 200 to be pulled toward the PCB 245 and held tightly against the heat generating device 250. The conduction side 207 of the contact structure 205 may then be in direct (or indirect) thermal communication with the heat generating device 250 to provide improved heat transfer characteristics.

FIG. 3 is a force diagram of a combination of an attachment structure 315 and a contact structure 305 in an example embodiment of the present invention annotated with forces exerted by the attachment structure 315 on the heat generating device 350. In this example embodiment, the heat generating device 350 is an integrated circuit secured to a PCB 345 via a BGA 355. In some example embodiments of the present invention, the forces may be exerted in a manner that does not affect a mechanical arrangement between the heat generating device 350 and a member 345 to which the heat generating device 350 is coupled. In the example embodiment of FIG. 3, the combination of the attachment structure 315 and the contact structure 305 exerts forces substantially uniformly across all solder joints 357 of the BGA 355. Each arrow indicating a force is only intended to indicate the direction component of the force vector and not the magnitude relative to the other arrows.

The heat sink 300 increases reliability of the heat generating device 350 by not exerting stresses non-uniformly upward, or downward, or a combination thereof, on the solder joints of the BGA 355. By attaching the heat sink 300 to the PCB 345, the forces are supported by the PCB 345. This makes the heat sink 300 suitable for high vibration and shock environments.

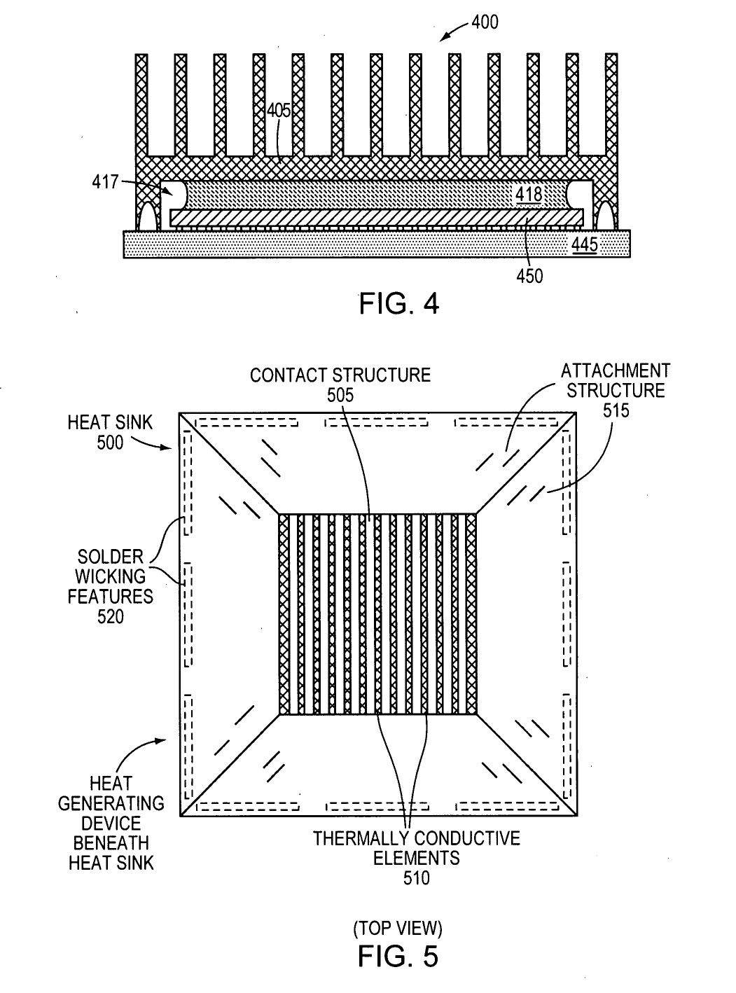

FIG. 4 is a cross sectional diagram of a heat sink 400, PCB 445, heat generating device 450, and gap pad material 418. The gap pad material 418 may be used in some applications to account for any excess height of the cavity 417 above the heat generating device 450 to ensure thermal communication between the heat generating device 450 and the heat sink 400. The gap pad material 418 may be of a springing or flexible nature with good thermal conduction properties such that it creates a positive mechanical force toward a contact plate 405 of the heat sink 400 and the heat generating device 450 and be a suitable thermal interface between the heat generating device 450 and the heat sink 400.

FIG. 5 is a top view diagram of a heat sink 500 with an attachment structure 515 having faces that extend from a contact structure 105 at an angle. The heat sink 500 may also have thermally conductive elements 510 extending from the contact structure 505. In this arrangement, the heat sink 500 may provide heat transfer and EMI shielding to other drives with the cavity 517 while reducing the volume of the cavity 517 as well as the amount of material used to form the heat sink 500. The heat sink 500 may be secured, as discussed above with reference to FIG. 2, by solder wicking features 520 which are not plainly visible in this top view but are located on the attachment structure 515 where it comes in contact with the member, such as a PCB, to which the heat generating device is coupled.

It should be understood that the solder wicking features may be any one of or a combination of pegs, slots, ridges, long and narrow grooves, or any other type of structural feature that allows for the securing of a heat sink to a PCB while maintaining thermal communication with a heat generating device by forces exerted on the heat sink by flowed and cooled solder.

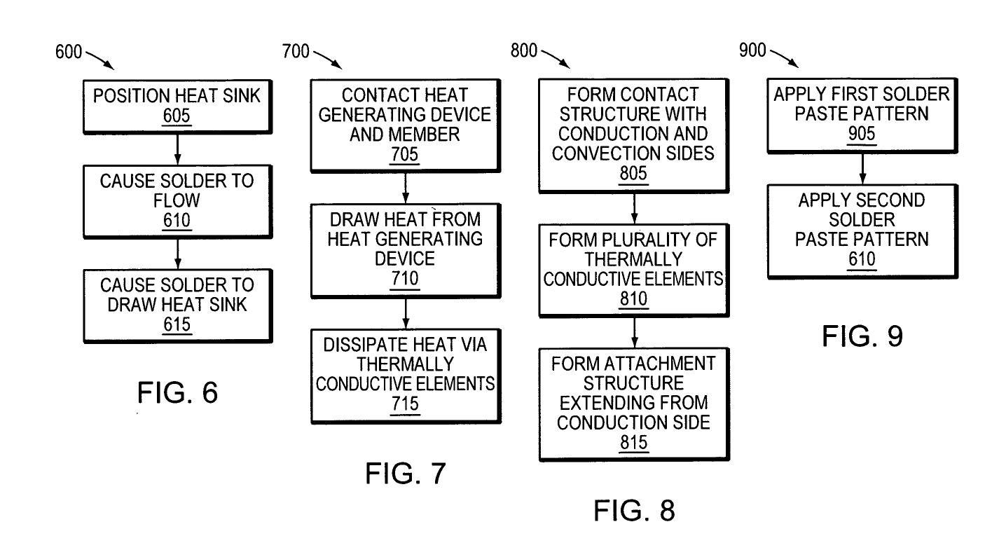

FIG. 6 is a flow diagram 600 illustrating a method by which a heat sink may be secured. First, the heat sink must be positioned 605 relative to a heat generating device in a configuration in which the heat sink contacts a solder paste pattern deposited on a surface of a member to which the heat generating device is coupled. Next, the solder must be caused to flow 610, such as by heating. The solder is then caused to draw the heat sink toward the member 615 during a transition of the solder from the state of flow to a state of being a solid. Simultaneous contact between the heat sink with the heat generating device and the surface of the member is maintained. The heat sink may be positioned via a pick and place feature.

FIG. 7 is a flow diagram 700 illustrating a method by which heat may be dissipated. First, simultaneous contact must be maintained with a heat generating device and a surface of a member to which the heat generating device is coupled 705. Heat may then be drawn from the heat generating device 710. Next, the heat drawn from the heat generating device may be dissipated via convection away from a plurality of thermally conductive elements.

FIG. 8 is a flow diagram 800 illustrating a method of manufacturing a heat sink. First, a contact structure is formed 805 have a conduction side and a convection side. Next, a plurality of thermally conductive elements are formed 810 extending outward from the convection side of the contact structure. Finally, an attachment structure is formed 815 extending from the conduction side of the contact structure for a distance defining a cavity, the attachment structure configured to be coupled, by less than or equal to a thickness of the attachment structure, to a surface of a member to which a heat generating device is coupled, the cavity having a volume defined by the length and the width of the contact structure and at least the height of the heat generating device as coupled to the member.

FIG. 9 is a flow diagram 900 illustrating a method for preparing a circuit board for receiving an electronic component. A first surface mount solder paste pattern is applied 905 to a surface of the circuit board to receive an electronic component. Next, a second surface mount solder paste pattern is applied 910 to the surface of the circuit board, in proximity to the first surface mount solder paste pattern, to receive a heat sink configured to be surface mounted in an arrangement to draw heat from the electronic component, wherein the second surface mount solder paste pattern has a thickness corresponding to the thickness of a solder wicking feature of the heat sink configured to wick solder in a state of flow and draw the heat sink toward the circuit board during a transition of the solder from the state of flow to a state of being a solid.

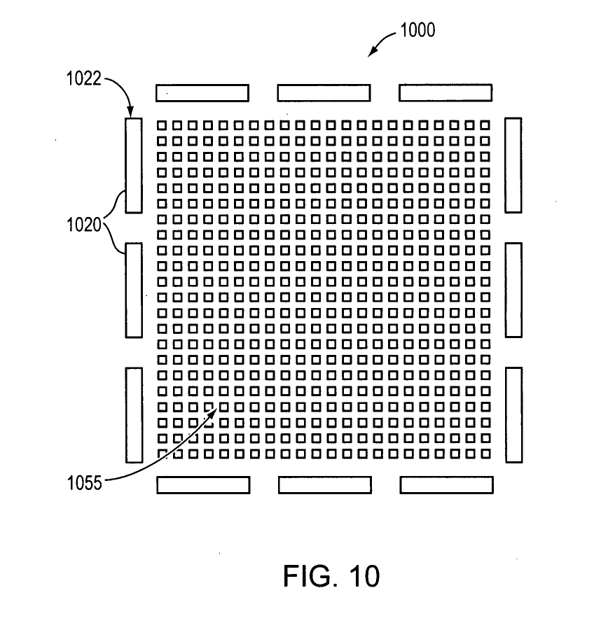

FIG. 10 is a diagram of an example mask 1000, according to an example embodiment of the present invention, with a solder paste pattern 1020 corresponding to a pattern of structural components on an attachment structure of a heat sink. The pattern 1020 has a thickness 1022 substantially corresponding to a thickness of a solder wicking feature of the heat sink. The thickness 1022 may be less than the thickness of the pattern of structural components on the attachment structure of the heat sink with the mask 1000 covering the portions actually contacting a circuit board. The mask 1000 may also have a solder paste pattern 1055 corresponding to a pattern of structural components on a heat generating device.

FIGS. 6-9 are flow diagrams illustrating methods according to example embodiments of the present invention. The techniques illustrated in these figures may be performed sequentially, in parallel or in an order other than that which is described. It should be appreciated that not all of the techniques described are required to be performed, that additional techniques may be added, and that some of the illustrated techniques may be substituted with other techniques.

While this invention has been particularly shown and described with references to example embodiments thereof, it will be understood by those skilled in the art that various changes in form and details may be made therein without departing from the scope of the invention encompassed by the appended claims.

What is claimed is:

1. A heat sink comprising:
a contact structure with a conduction side and a convection side, the conduction side configured to be in thermal communication with a heat generating device and the convection side configured to be in thermal communication with the heat generating device via the conduction side;
a plurality of thermally conductive elements extending outward from the convection side of the contact structure; and
an attachment structure extending from the conduction side of the contact structure for a distance defining a cavity, the attachment structure configured to be coupled, by less than or equal to a thickness of the attachment structure, to a surface of a member to which the heat generating device is coupled, the cavity having a volume defined by the length and the width of the contact structure and at least the height of the heat generating device as coupled to the member.

2. The heat sink of claim 1 wherein the attachment structure defines a solder wicking feature configured to wick solder in a state of flow and draw the attachment structure toward the member during a transition of the solder from the state of flow to a state of being a solid.

3. The heat sink of claim 2 wherein the wicking feature is within a thickness of the attachment structure.

4. The heat sink of claim 2 wherein the attachment structure further defines a flange extending substantially parallel to the surface of the member.

5. The heat sink of claim 1 wherein the attachment structure extends substantially perpendicularly from the conduction side to the member.

6. The heat sink of claim 1 wherein the attachment structure extends non-perpendicularly at an angle from the conduction side to the member.

7. The heat sink of claim 1 wherein the thermally conductive elements provide more convection surface area than plate elements with flat surfaces.

8. The heat sink of claim 1 wherein the thermally conductive elements are configured to increase airflow across them.

9. The heat sink of claim 1 wherein the thermally conductive elements define a pick and place feature.

10. The heat sink of claim 1 wherein a pick and place feature is included in place of at least one thermally conductive element.

11. The heat sink of claim 1 wherein the contact structure in combination with the attachment structure substantially encompasses the heat generating device on five sides to contain electromagnetic interference (EMI) radiation generated by the heat generating device and provide EMI immunity for the heat generating device.

12. The heat sink of claim 1 wherein the attachment structure includes structural components selected from a group consisting of: pegs, slots, ridges, solder wicking.

13. The heat sink of claim 1 wherein, as deployed on a circuit board member, the attachment structure has a thickness sufficiently thin to be mechanically between the heat generating device and AC filter capacitors coupled to the heat generating device.

14. The heat sink of claim 1 wherein the cavity is further configured to encompass other devices in addition to the heat generating device.

15. A heat sink comprising:
a contact structure with a conduction side and a convection side, the conduction side configured to be in thermal communication with a heat generating device and the convection side configured to be in thermal communication with the heat generating device via the conduction side;
a plurality of thermally conductive elements extending outward from the convection side of the contact structure; and
an attachment structure extending from the conduction side of the contact structure for a distance defining a cavity, the attachment structure configured to be coupled to a surface of member to which the heat generating device is coupled, the cavity having a volume defined by the length and the width of the contact structure and at least the height of the heat generating device as coupled to the support structure, wherein the attachment structure defining a solder wicking feature configured to wick solder in a state of flow and draw the attachment structure toward the member during a transition of the solder from the state of flow to a state of being a solid.

16. A method of securing a heat sink to a member, the method comprising:
positioning the heat sink relative to a heat generating device in a configuration in which the heat sink contacts a solder paste pattern deposited on a surface of a member to which the heat generating device is coupled;
causing the solder to enter a state of flow;
enabling the solder to draw the heat sink toward the member during a transition of the solder from the state of flow to a state of being a solid to cause simultaneous contact between the heat sink with the heat generating device and the surface of the member following return of the solder to the state of being a solid.

17. The method of claim 16 further comprising positioning the heat sink via a pick and place feature.

18. A method of manufacturing a heat sink comprising:
forming a contact structure with a conduction side and a convection side;
forming a plurality of thermally conductive elements extending outward from the convection side of the contact structure; and
forming an attachment structure extending from the conduction side of the contact structure for a distance defining a cavity, the attachment structure configured to be coupled, by less than or equal to a thickness of the attachment structure, to a surface of a member to which a heat generating device is coupled, the cavity having a volume defined by the length and the width of the contact structure and at least the height of the heat generating device as coupled to the member.

19. A method for preparing a circuit board for receiving an electronic component comprising:
applying a first surface mount solder paste pattern to a surface of the circuit board to receive an electronic component; and
applying a second surface mount solder paste pattern to the surface of the circuit board, in proximity to the first surface mount solder paste pattern, to receive a heat sink configured to be surface mounted in an arrangement to draw heat from the electronic component, the second surface mount solder paste pattern having a thickness substantially corresponding to the thickness of a solder wicking feature of the heat sink configured to wick solder in a state of flow and draw the heat sink toward the circuit board during a transition of the solder from the state of flow to a state of being a solid.

20. A mask with a solder paste pattern corresponding to a pattern of structural components on an attachment structure of a heat sink, the pattern having a thickness substantially corresponding to a thickness of a solder wicking feature of the heat sink.

21. The mask of claim 20 wherein the solder paste pattern further corresponds to a pattern of structural components on a heat generating device.
